(19) United States
(12) Patent Application Publication
(10) Pub. No.: US 2013/0083038 A1
(43) Pub. Date: Apr. 4, 2013

(54) METHODS OF CREATING SPACERS BY SELF-ASSEMBLY

(71) Applicant: Rihui HE, San Jose, CA (US)

(72) Inventor: Rihui HE, San Jose, CA (US)

(73) Assignee: QUALCOMM MEMS TECHNOLOGIES, INC., San Diego, CA (US)

(21) Appl. No.: 13/252,109

(22) Filed: Oct. 3, 2011

(51) Int. Cl. G06T 1/00; H01L 23/04; H01L 21/56

(52) U.S. Cl. 345/501; 438/126; 257/704; 257/E21.502; 257/E23.181

(57) ABSTRACT

This disclosure provides systems, methods and apparatus for fabricating spacers for electromechanical systems devices. In one aspect, a method of forming a spacer on a spacer portion of a device surface of an electromechanical systems device includes exposing the device surface to spacer particles suspended in a fluid. The spacer particles are allowed to attach to the spacer portion. Each of the spacer particles can have at least one dimension of about 1 micron to 10 microns. The electromechanical systems device can also include a sacrificial layer that is subsequently removed between the device surface and a substrate surface of a substrate on which the electromechanical systems device is formed.

### TECHNICAL FIELD

This disclosure relates generally to spacers for electromechanical systems devices and more particularly to fabrication methods for spacers for electromechanical systems devices.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

An EMS device may be packaged to protect it from the environment and from operational hazards, such as mechanical shock. One packaging method for an EMS device involves bonding a cover to a substrate on which the EMS device is disposed, with the cover encapsulating the EMS device between the cover and the substrate.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of forming a spacer on an electromechanical systems device. The electromechanical systems device may include a spacer portion of a device surface on which the spacer will be formed. The device surface may include an active area and a post area exclusive of the active area, with the spacer portion being formed over the post area. The electromechanical systems device may also include a sacrificial layer between the device surface and a substrate surface of a substrate on which the electromechanical systems device is formed. Forming the spacer may include exposing the device surface to spacer particles suspended in a fluid. The spacer particles may be allowed to attach to the spacer portion. Each of the spacer particles may have at least one dimension of about 1 micron to 10 microns.

In some implementations, a plurality of the spacers may be formed to form an array of the spacers on the device surface. Each spacer in the array may be positioned about 30 microns to 300 microns apart. A center of the array may have a greater density of spacers than a periphery of the array. Forming the plurality of the spacers may include treating a plurality of spacer portions of the device surface to render the plurality of spacer portions of the device surface substantially hydrophobic. After treating the plurality of spacer portions of the device surface, the device surface may be exposed to the spacer particles suspended in the fluid, with the spacer particles being substantially hydrophobic.

In some implementations, a cover may be bonded to the substrate surface. The cover may encapsulate the electromechanical systems device between the cover and the substrate. In some implementations, the spacer may be disposed between the cover and the device surface. In some implementations, the spacer may be configured such that when a pressure is applied to the cover, the spacer prevents contact between the cover and the device surface.

One innovative aspect of the subject matter described in this disclosure can be implemented in a method of forming a plurality of spacers on a plurality of attachment sites on a device surface of an electromechanical systems device by exposing the device surface to spacer particles suspended in a fluid. The spacer particles may include particles having at least one dimension of about 1 micron to 10 microns. Each of the plurality of spacers may be positioned about 30 microns to 300 microns apart from one another on the device surface. Forming the plurality of spacers may include treating the plurality of attachment sites on the device surface to render the plurality of attachment sites on the device surface substantially hydrophobic. After treating the plurality of attachment sites on the device surface, the device surface may be exposed to the spacer particles suspended in the fluid, with the spacer particles being substantially hydrophobic. After forming the plurality of spacers, a sacrificial layer may be removed from the electromechanical systems device. A cover may be bonded to a substrate surface on which the electromechanical systems device is formed to encapsulate the electromechanical systems device between the cover and the substrate.

One innovative aspect of the subject matter described in this disclosure can be implemented in an apparatus including an electromechanical systems device formed on a substrate. The electromechanical systems device may be formed on a surface of the substrate and may include a first device layer and a second device layer. The first device layer and the second device layer may define a gap. A cover may be bonded to the substrate surface. The cover may encapsulate the electromechanical systems device between the cover and the substrate. A self-assembled spacer may be on a device surface of the second device layer. The spacer may include one or more spacer particles. The spacer particles may have at least one dimension greater than about 1 micron. The spacer may be configured to prevent contact between the cover and the device surface.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a top-down view of an array of post areas in an array of electromechanical devices, such as interferometric modulators.

FIG. 10 shows an example of a flow diagram illustrating a manufacturing process for an electromechanical systems assembly including a spacer.

FIG. 11 shows an example of a flow diagram illustrating a manufacturing process for forming a spacer for an electromechanical systems assembly.

FIGS. 12A-12F show examples of schematic illustrations of various stages in a manufacturing process for an electromechanical systems assembly including a spacer.

FIG. 13A shows an example of a flow diagram illustrating a manufacturing process for forming a spacer for an electromechanical systems assembly.

FIGS. 13B and 13C show examples of cross-sectional schematic illustrations of a spacer portion and spacer particles according to the manufacturing process shown in FIG. 13A.

FIGS. 14 and 15 show examples of flow diagrams illustrating manufacturing processes for an electromechanical systems assembly including a spacer.

FIGS. 16A and 16B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein are related to methods of forming spacers for an EMS device. Spacers may prevent an active surface of an EMS device from coming into contact with a cover or backplate. The substrate on which the EMS device is formed along with the backplate together serve to encapsulate the EMS device.

For example, in some implementations, a substrate including an EMS device on the surface of the substrate may be provided. A spacer may be formed on a spacer portion of a device surface of the EMS device by exposing the device surface to spacer particles suspended in a fluid and allowing the spacer particles to attach to the spacer portion. Each of the spacer particles may have at least one dimension of about 1 micron to 10 microns.

Particular implementations of the subject matter described in this disclosure can be implemented to realize one or more of the following potential advantages. Implementations of the methods may be used to economically form a spacer. The spacer may be formed on the spacer portion of the EMS device surface. Etching or other material removal methods may not need to be employed to remove spacer material from portions of the device surface other than the spacer portion; the spacer material may not form on portions of the device surface other than the spacer portion according to the methods described herein.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

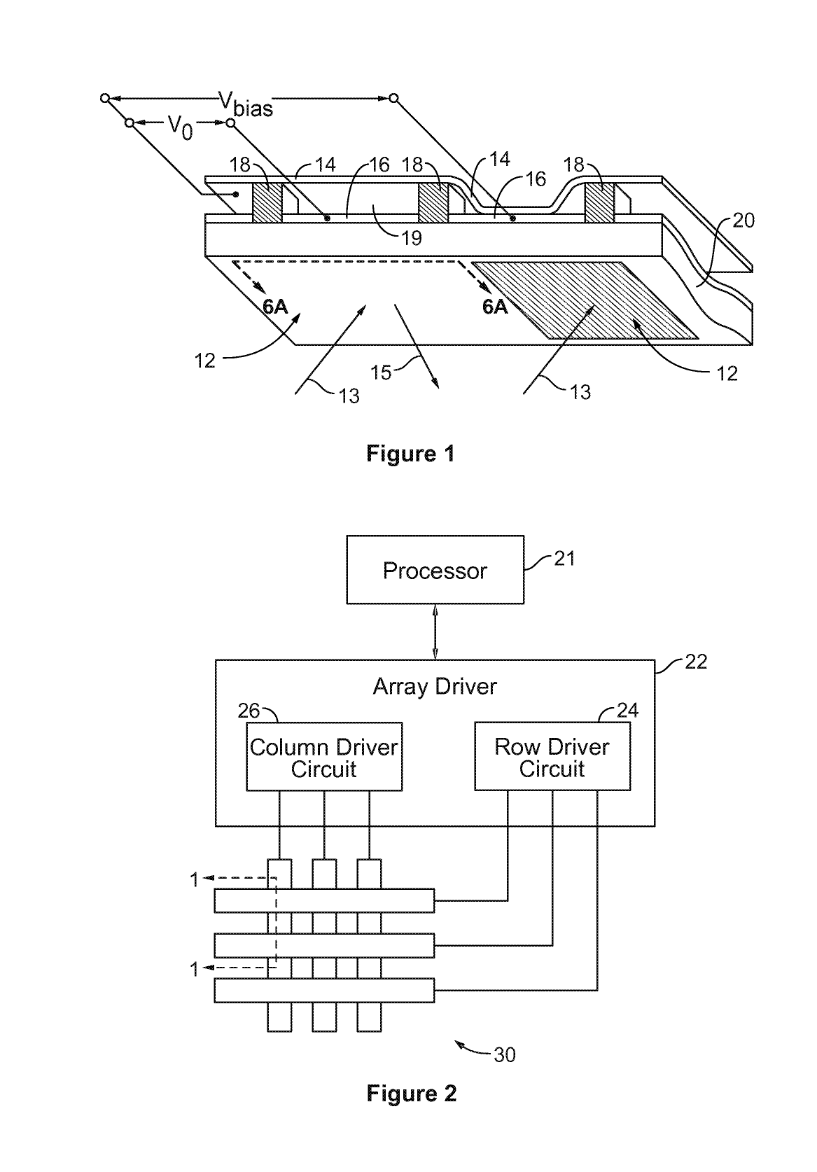

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (e.g., of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

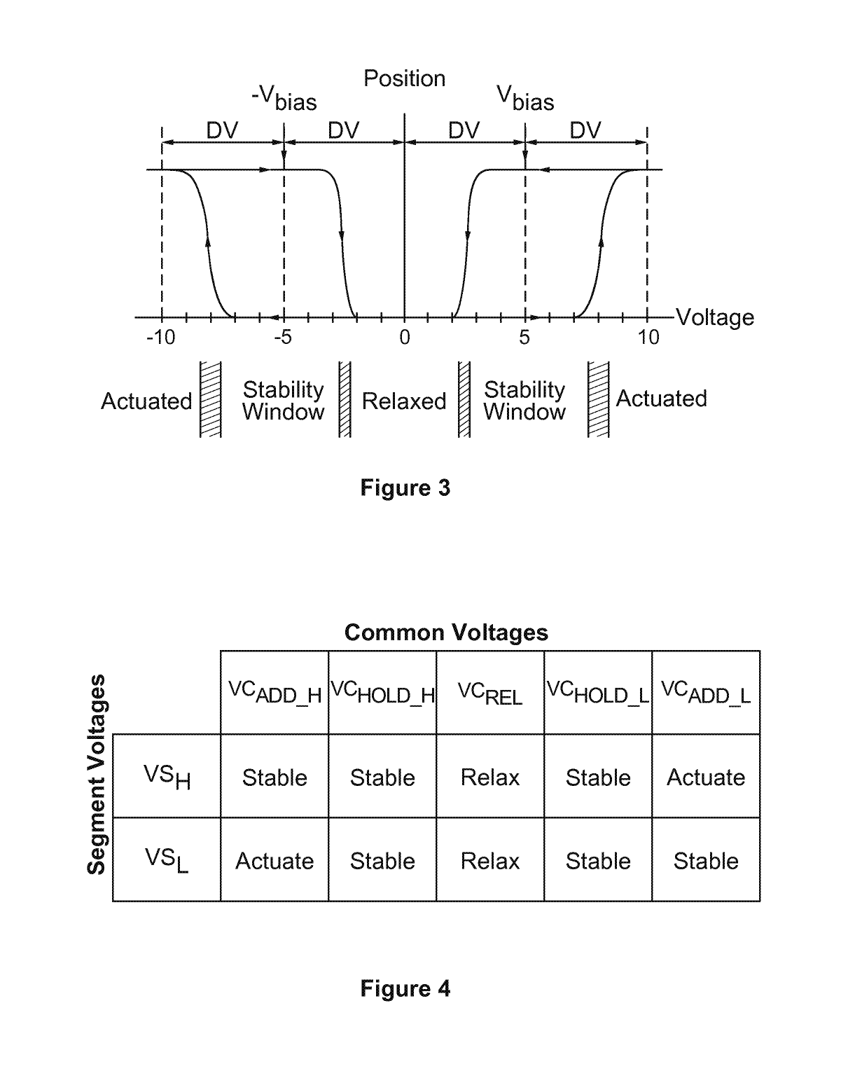

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

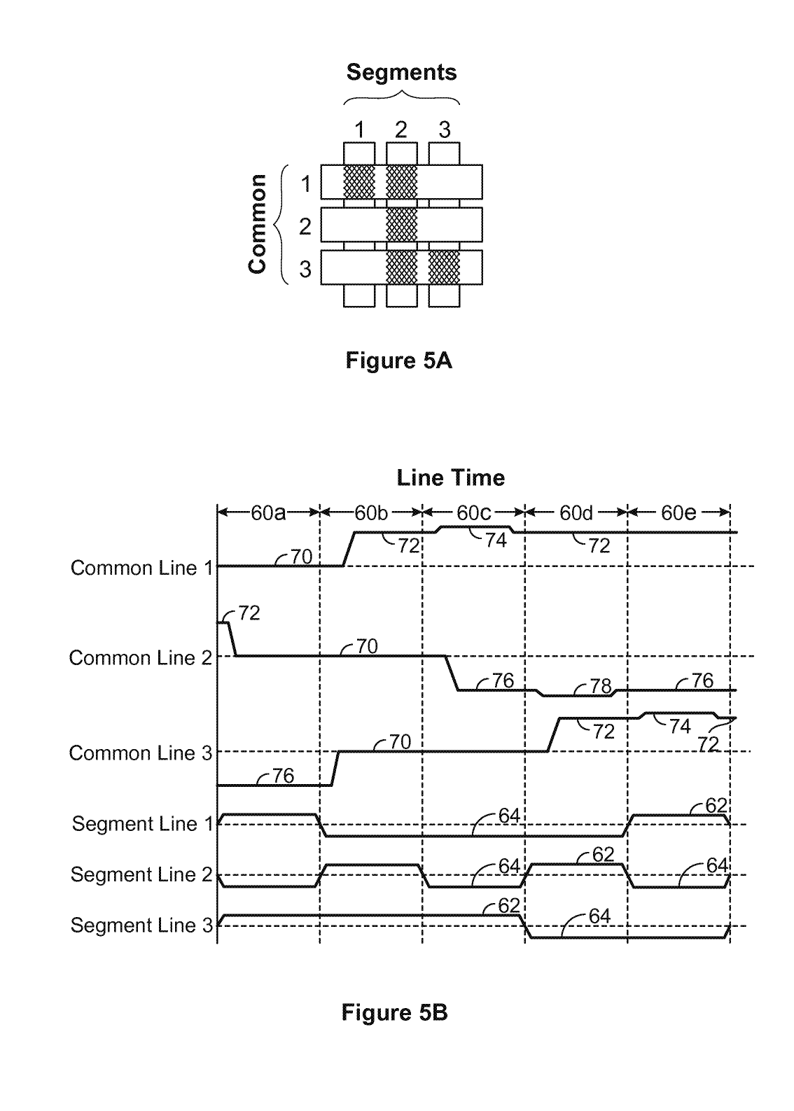

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

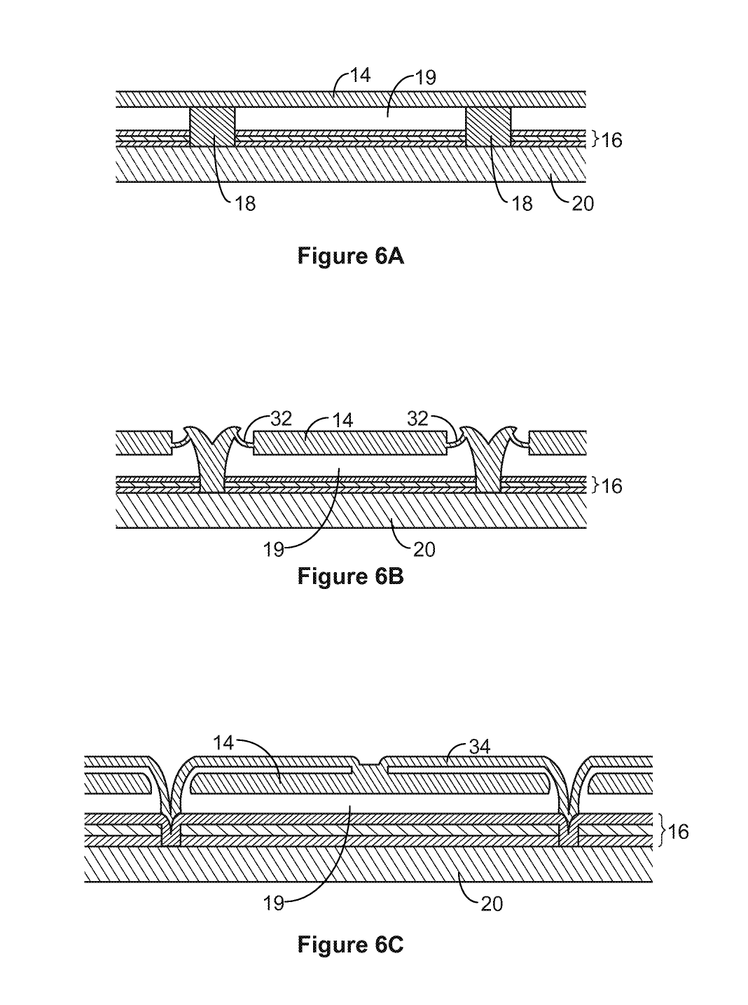

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

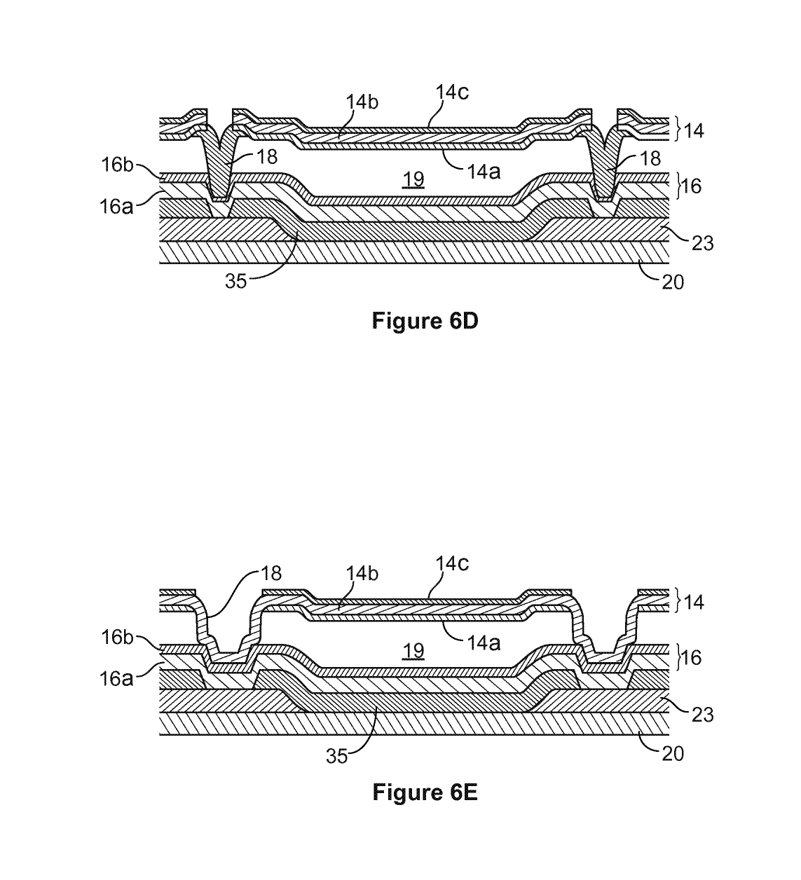

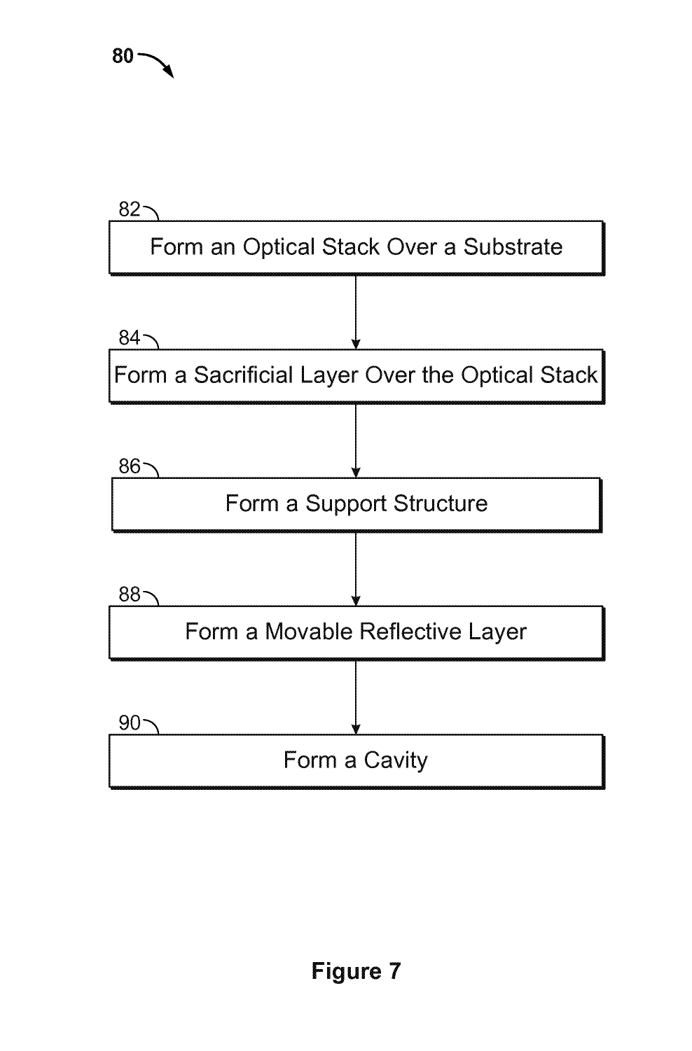

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—L}}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

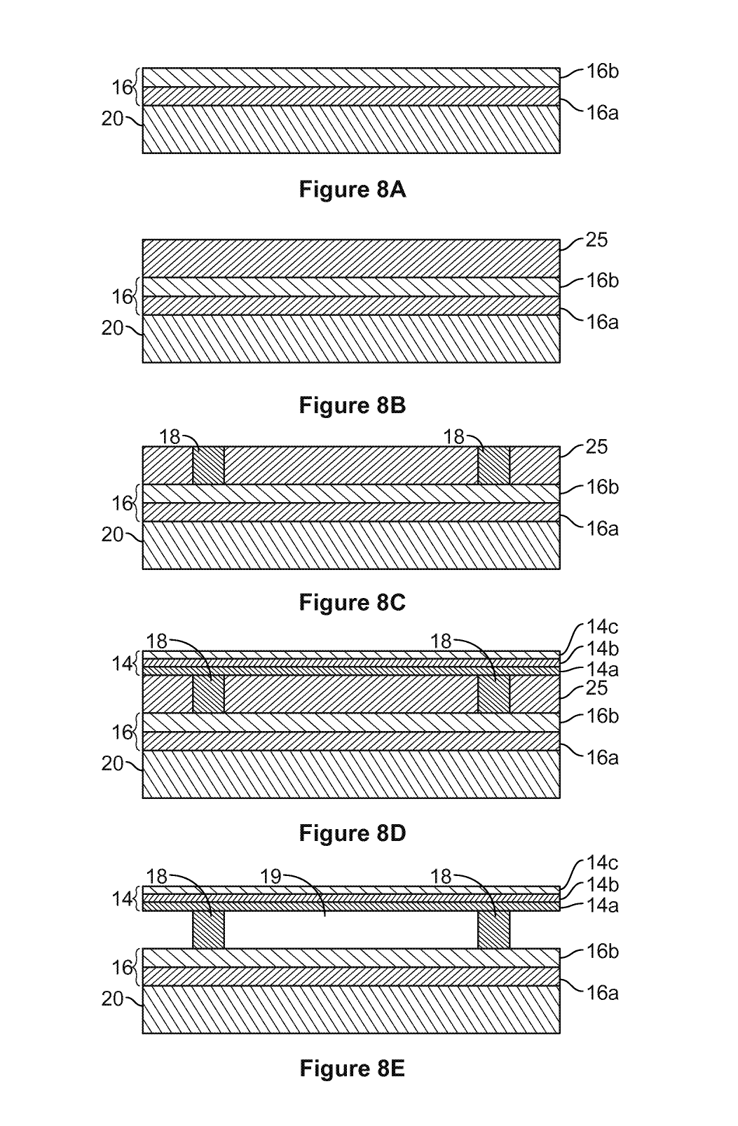

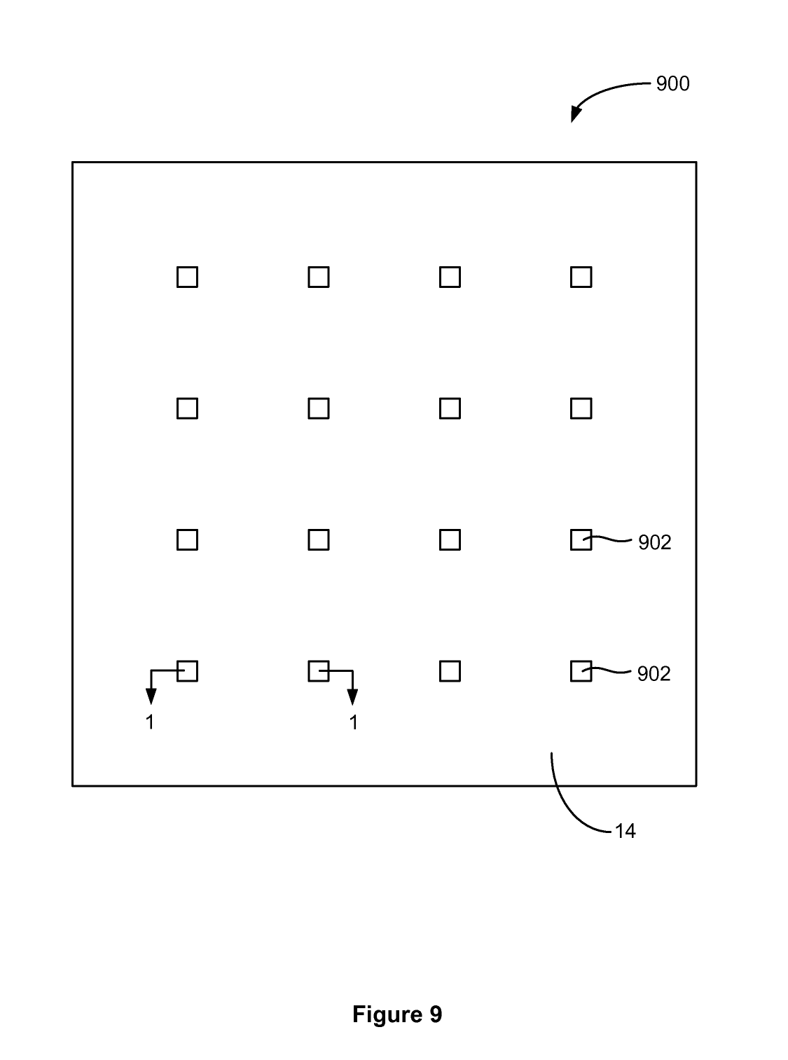

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In some implementations, the optical absorber 16a is an order of magnitude (ten times or more) thinner than the movable reflective layer 14. In some implementations, the optical absorber 16a is thinner than reflective sub-layer 14a.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

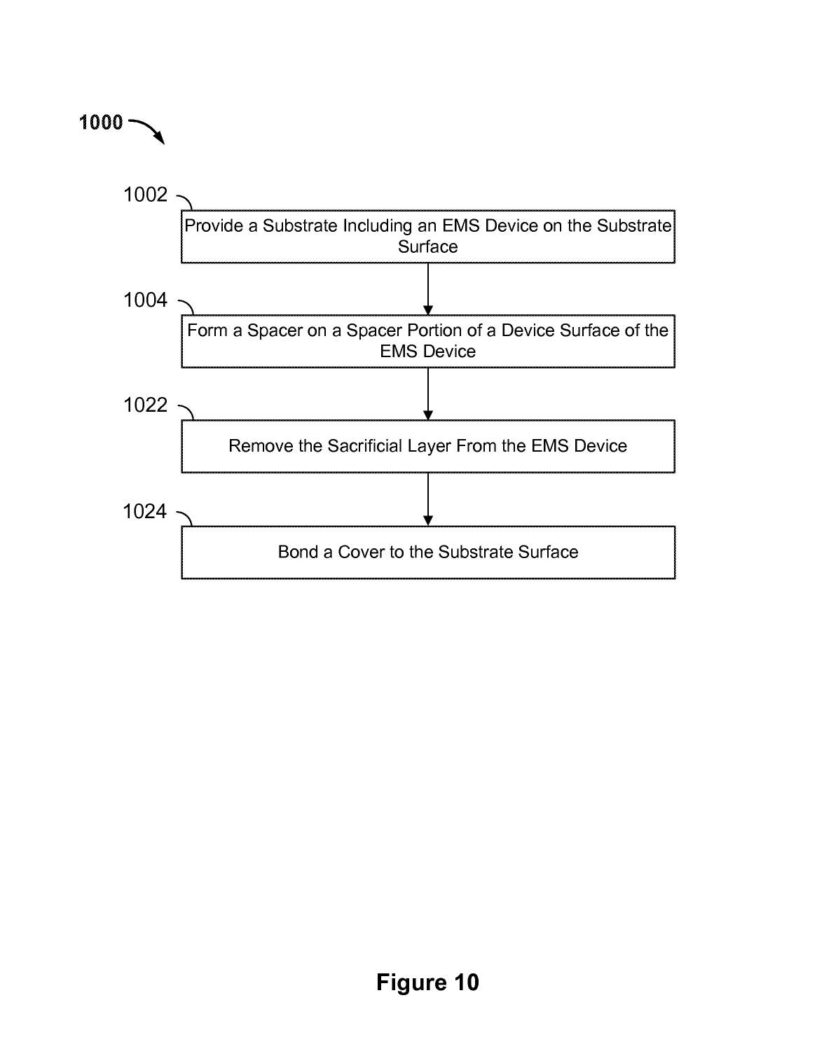

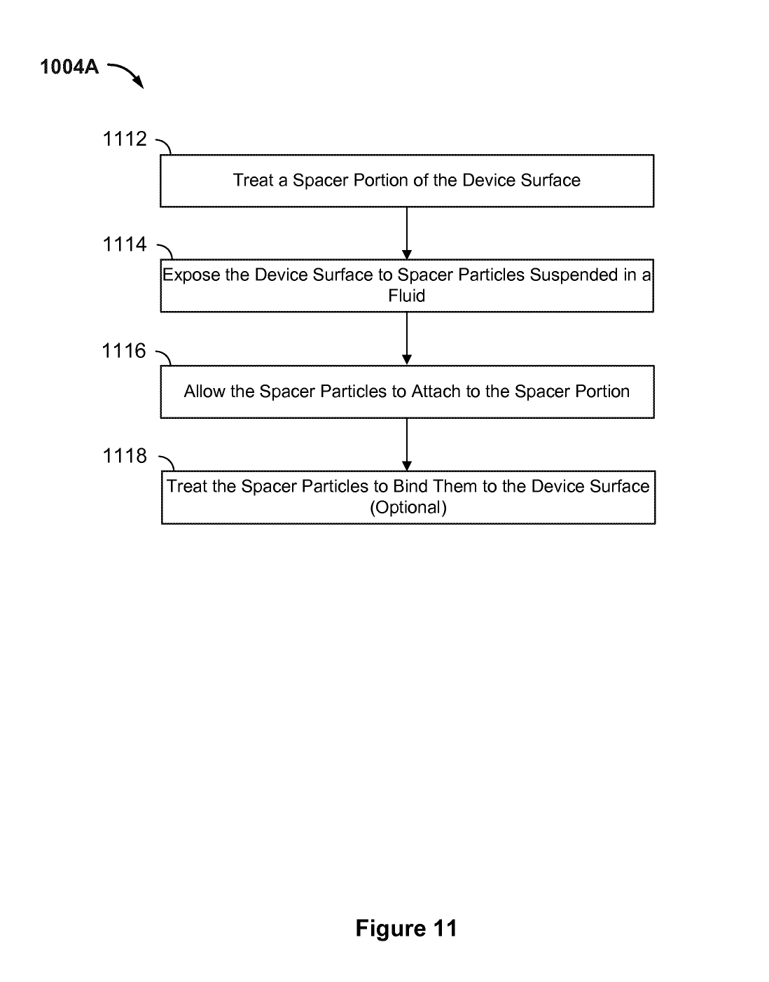

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6. The manufacture of an electromechanical systems device can also include other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown to be somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18, illustrated in FIGS. 1, 6 and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps including, for example, reflective layer (such as aluminum, aluminum alloy, or other reflective layer) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As noted above, an IMOD display device can include a row/column array of IMODs. Other EMS devices may also be arranged in arrays. An array of IMODs or other EMS devices may include both inactive areas, which may also be referred to as post areas, and active areas. Inactive areas may not move and/or deform, while active areas may move and/or deform. For example, referring to FIG. 6A, the area of the moveable reflective layer 14 overlying the supports 18 is a post area, and the area of the moveable reflective layer 14 overlying the gap 19 is an active area.

In some implementations, a cover may be bonded to the substrate to encapsulate an array of IMODs or other EMS devices between the cover and the substrate. Bonding a cover to the substrate to encapsulate an array of IMODs or other EMS devices is a form of macro-encapsulation, which is different from thin-film encapsulation techniques. The cover of an array of EMS devices, however, may contact the active region of an underlying EMS device when the array is handled by a user (for example, as when the EMS device is a display device and the display device is integrated with a touch screen) and render the EMS device inoperable. In some implementations, spacers may be formed on the post areas of an array of EMS devices which may help to prevent the cover from contacting active regions of the array of EMS devices.

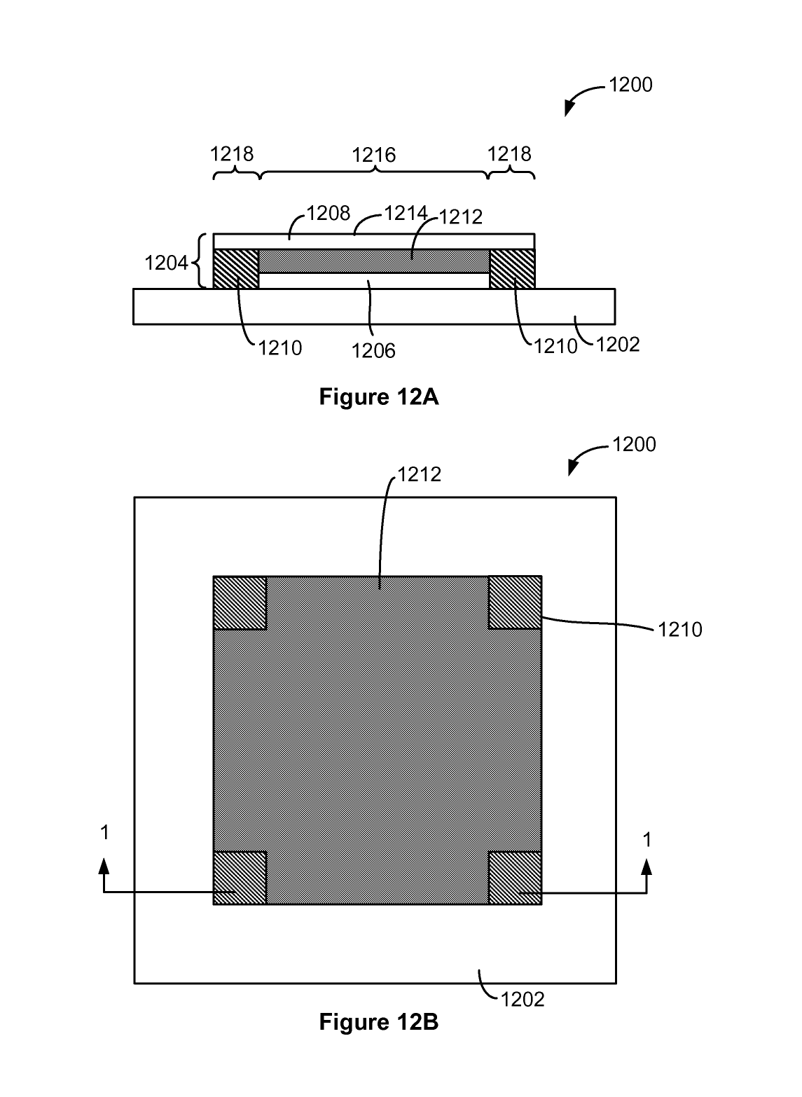

FIG. 9 shows an example of a top-down view of an array of post areas in an array of EMS devices, such as interferometric modulators. The post-area array 900 shown in FIG. 9 may be formed on the surfaces of an array of IMODs that can include hundreds, thousands or even millions of IMODs. Example dimensions of such an IMOD array may be 1 inch, 4 inches, or 5.7 inches measured across a diagonal of the IMOD array. The post-area array 900 is shown from the side of the moveable reflective layer 14. The moveable reflective layer 14 includes a plurality of post areas 902. FIG. 6A, 6D or 6E, for example, could be the cross-sectional schematic view of an IMOD though line 1-1 of FIG. 9, with the post areas 902 being over the supports 18 of the IMOD.

Pressure applied to a packaged device, such as handling or touching of a substrate for an IMOD array or a backplate/cover (not shown) for an IMOD array, may bring the cover into contact with active areas of the moveable reflective layer 14. To help prevent contact between the active areas of the moveable reflective layer 14 and the cover, spacers may be formed on the post areas 902. To facilitate the forming of spacers on some or all of the post areas 902, an array of attachment sites may be formed on some or all of the post areas 902 in the post-area array. Depending on the pressure expected in the operational environment of the IMOD array, the distribution of spacers in the post-area array 900 can be adjusted so that spacers may be formed on all or some of the post areas 902. For example, if high pressures are expected in the operational environment of the IMOD array, a spacer may be formed on every post area 902. If instead low pressures are expected in the operational environment of the IMOD array, the post-area array 900 can include a spacer formed on every other post area 902 or a few post areas 902 that are separated from one another. In some implementations, a greater density of spacers may be formed at a center of the post-area array 900 than on the periphery of the post-area array. In some other implementations, the ratio of spacers to individual IMODs may be 1 to 1 (i.e., one spacer for every IMOD), 1 to 3, 1 to 4, or 1 to 9. For some IMOD display devices, a force of about 5 newtons (N) or less may be expected in the operational environment of the display. Hence, in some implementations, spacers may be formed that are capable of withstanding a force of about 5 N.

While FIG. 9 depicts an IMOD array, FIG. 9 could include an array of EMS devices other than IMODs. For example, FIG. 9 could include an array of other EMS devices that are together capable of forming a display. As another example, FIG. 9 could include an array of EMS devices that are capable of generating a sound or sensing a sound. While the spacers and methods of forming the spacers disclosed herein may be applied to any EMS device or array of EMS devices, the discussion that follows will be directed to implementations with an IMOD similar to those described above.

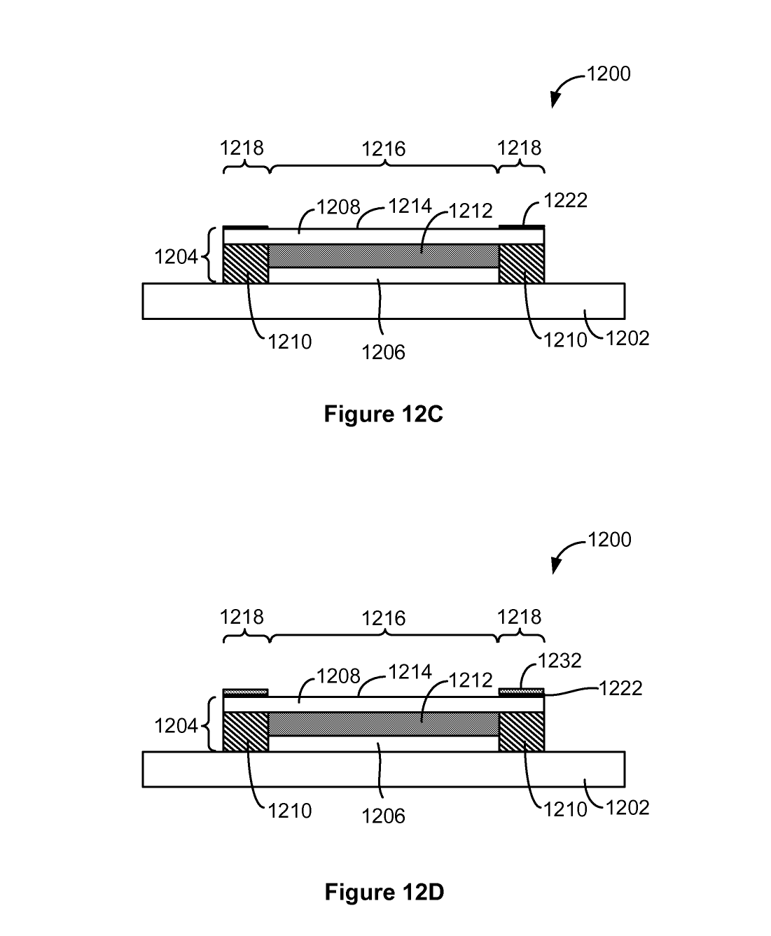

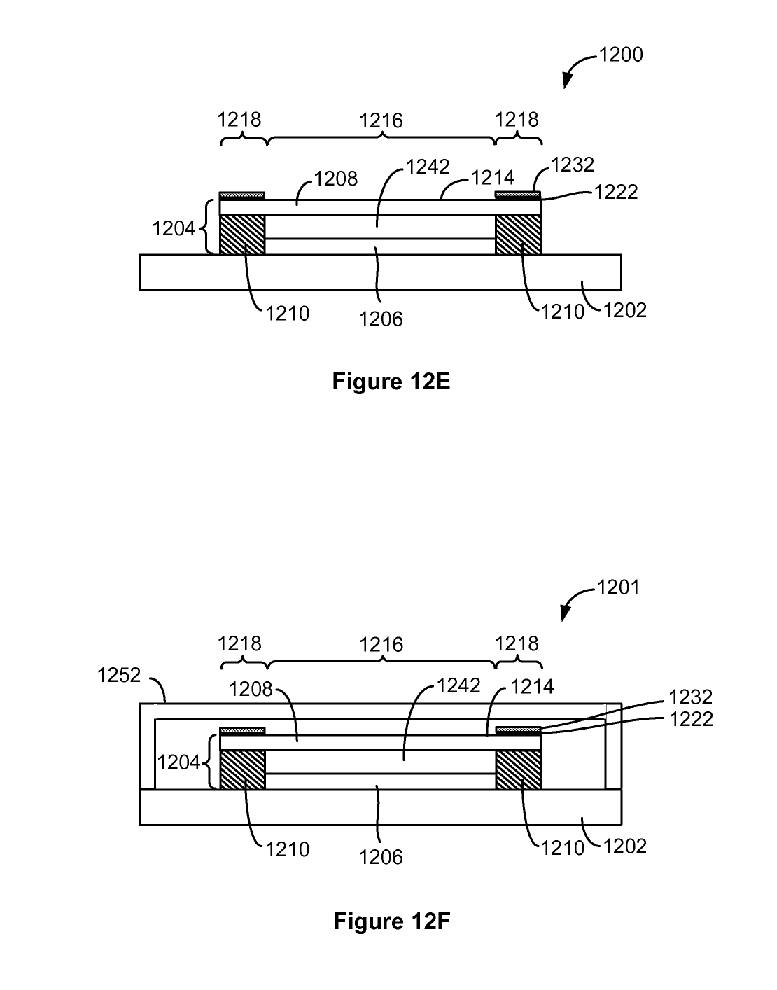

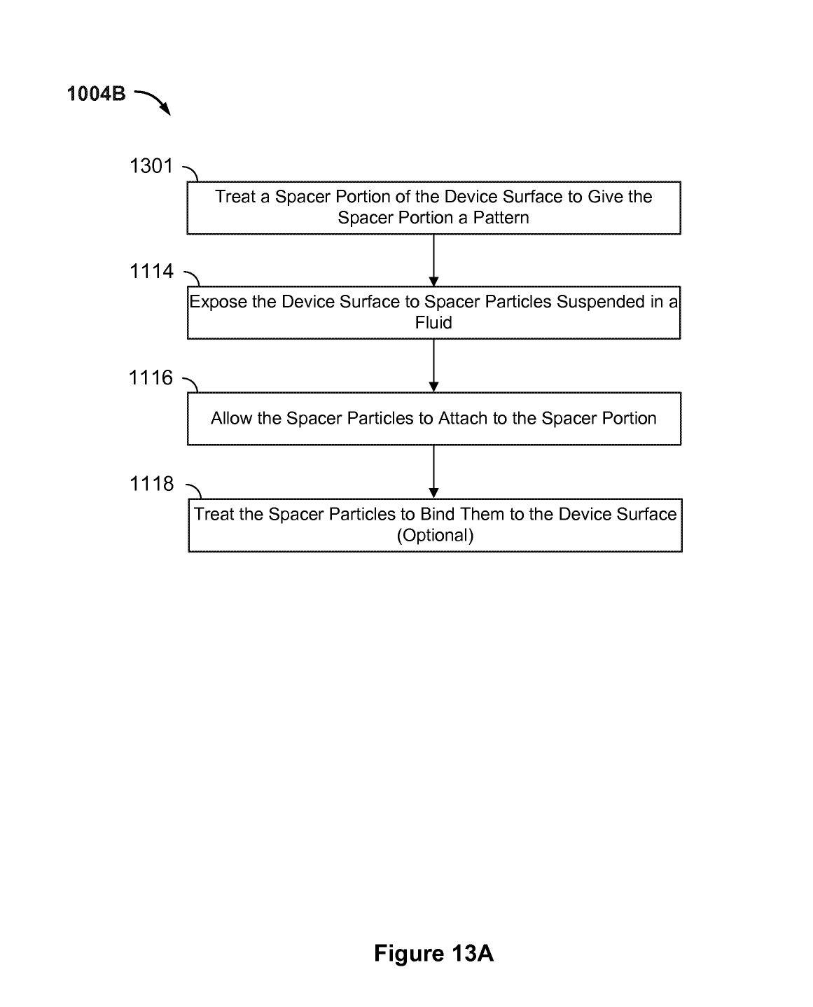

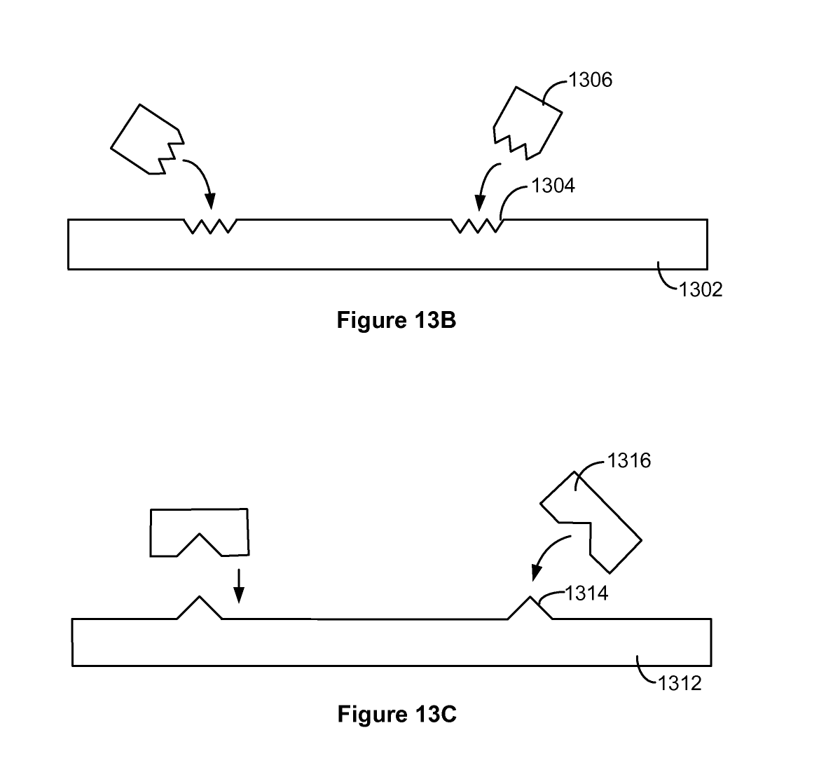

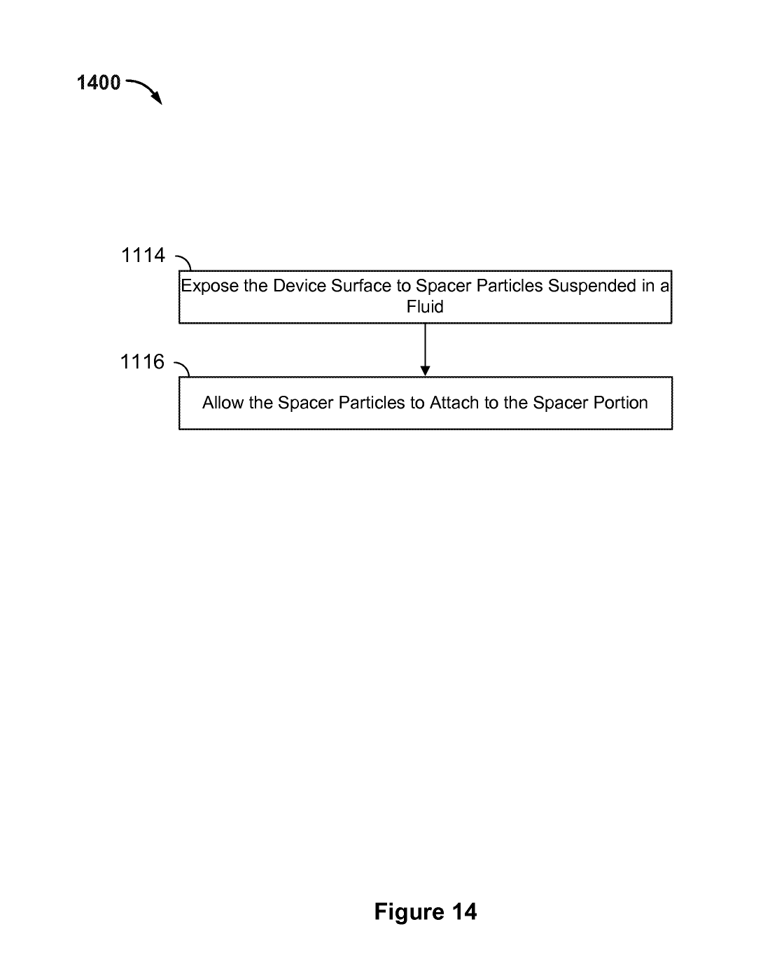

Many different techniques may be used to fabricate spacers for an EMS device or an array of EMS devices. In the following description of techniques that may be used to fabricate spacers for an EMS device or an array of EMS devices, an EMS assembly refers to an EMS device or devices on a substrate with any associated cover or related components. FIGS. 10 and 11 show an example of one technique for fabricating spacers for an EMS device or an array of EMS devices. FIG. 10 shows an example of a flow diagram illustrating a manufacturing process for an electromechanical systems assembly including a spacer. FIG. 11 shows an example of a flow diagram illustrating a manufacturing process for forming a spacer for an electromechanical systems assembly. FIGS. 12A-12F show examples of schematic illustrations of various stages in a manufacturing process for an electromechanical systems assembly including a spacer. Additional examples of flow diagrams illustrating manufacturing process for forming a spacer for an electromechanical systems assembly are shown in FIGS. 13A, 14, and 15.

Turning first to FIG. 10, at block 1002 of the process 1000, a substrate including an EMS device on the substrate surface is provided. In some implementations, the EMS device may include a sacrificial layer between a device layer of the EMS device and another device layer of the EMS device. In some implementations, the sacrificial layer may be between a device layer of the EMS device and the substrate surface.

FIG. 12A shows an example of cross-sectional schematic illustration of a partially fabricated EMS assembly 1200 at this point (for example, up to block 1002) in the process 1000 of FIG. 10. The partially fabricated EMS assembly 1200 includes a substrate 1202 and an EMS device 1204 on the substrate. The EMS device 1204 includes a first device layer 1206, a second device layer 1208, and a sacrificial layer 1212 between the first device layer 1206 and the second device layer 1208. The sacrificial layer 1212 may be present to aid in the formation of the second device layer 1208. Posts 1210 may support the second device layer 1208 when the sacrificial layer 1212 is removed.

In some implementations, the partially fabricated EMS assembly 1200 may be similar to interferometric modulator display shown in FIG. 6A. For example, the first device layer 1206 may include an optical stack on the substrate 1202 and also may include a plurality of layers. The second device layer 1208 may include a movable reflective layer. The second device layer 1208 and a device surface 1214 of the second device layer 1208 may include aluminum (Al), silicon oxynitride (SiON), or silicon nitride (SiN), in some implementations.

The device surface 1214 of the second device layer 1208 may include an active area 1216 and post areas 1218. For example, the active area 1216 of the device surface 1214 may include the surface over the sacrificial layer 1212 and the post areas 1218 of the device surface 1214 may include the surface over the posts 1210. Thus, the active area 1216 and the post areas 1218 of the device surface 1214 may be mutually exclusive.

The substrate 1202 may be any number of different substrate materials, including transparent materials and non-transparent materials. In some implementations, the substrate is silicon, silicon-on-insulator (SOI), a glass (for example, a display glass or a borosilicate glass), a flexible plastic, or a metal foil. In some implementations, the substrate on which an EMS device is fabricated has dimensions of a few microns to hundreds of microns to tens of centimeters. The posts 1210 may include a polymer or an inorganic material, such as silicon oxide. The sacrificial layer 1212 may be a fluorine-etchable material, such as molybdenum (Mo), tungsten (W), or amorphous silicon (Si).

FIG. 12B shows an example of a top-down schematic illustration of the partially fabricated EMS assembly 1200 at this point (for example, up to block 1002) in the process 1000 of FIG. 10. For clarity, the top-down view of the partially fabricated EMS assembly 1200 shown in FIG. 12B does not show the second device layer 1208. The partially fabricated EMS assembly 1200 includes the substrate 1202, the posts 1210, and the sacrificial layer 1212. The cross-sectional schematic illustration of the partially fabricated EMS assembly 1200 shown in FIG. 12A is a view though line 1-1 of FIG. 12B.

Returning to FIG. 10, at block 1004, a spacer is formed on a spacer portion of the device surface of the EMS device. In some implementations, the spacer is formed using a self-assembly technique. In some implementations, self-assembly techniques are processes in which objects or particles may form structures without an external driving force causing the objects or particles to form the structures. Examples of external driving forces may include heat, electromagnetic radiation, or other sources of energy. In some implementations, self-assembly techniques can refer to techniques of forming micro- or nano-scale structures without etching the material making up the structures themselves to form the structure, although lithography may be used in other parts of the process. Examples of process operations that may be included in block 1004 are described with reference to FIG. 11, which illustrates a manufacturing process 1004A for forming the spacer.

Turning now to FIG. 11, at block 1112, a spacer portion of the device surface is treated. In some implementations, the spacer portion of the device surface to be treated may be defined by photolithography. In some implementations, the spacer portion of the device surface is treated to make an attachment site for spacer particles to later attach to. In some implementations, making an attachment site includes rendering the spacer portion of the device hydrophobic or electrically charged. Spacers may then be formed by self-assembly by allowing hydrophobic or electrically charged spacer particles to attach to the attachment sites. In some implementations, the spacer portion of the device surface may be part of a post area of the device surface. In some implementations, the spacer portion includes the entire post area. In some other implementations, the spacer portion of the device surface includes only a portion of the post area. A spacer portion may have a dimension of about 1 micron to about 10 microns, in some implementations. The spacer portion also may be a number of different shapes. When the spacer portion is circular, for example, the diameter may be about 1 micron to 10 microns. When the spacer portion is rectangular or a square, for example, the diagonal of the rectangle or the square may be about 1 micron to 10 microns.

In some implementations, prior to treating the spacer portion of the device surface, the device surface may be substantially hydrophilic. In some implementations, treating the spacer portion of the device surface to make an attachment site includes rendering the spacer portion of the device surface substantially hydrophobic. Hydrophilic and hydrophobic are terms that refer to the degree that water wets a surface. Wetting phenomena are due to adhesive forces between a liquid and a surface and cohesive forces within the liquid. A liquid with a high degree of wetting of a surface will spread over a large area of the surface. In contrast, a liquid with a low degree of wetting of a surface will minimize contact with the surface and form a compact liquid droplet. A surface wettable by water may be termed hydrophilic and surface that is not wettable by water may be termed hydrophobic. While the remainder of this disclosure will describe implementations using hydrophobic attachment sites and hydrophobic spacer particles, it is understood that self-assembled spacers may be formed using other means of attaching spacer particles to the attachment sites. For example, attachments sites may be rendered electrically charged and then spacer particles with an opposite electrical charge may be allowed to attach to the attachment sites.

Many different techniques may be used to treat the spacer portion of the device surface to render the spacer portion substantially hydrophobic. For example, in some implementations, the treatment may include forming a hydrophobic polymer (for example, polyp-xylylene)) on the spacer portion of the device surface. In some other implementations, the treatment may include forming a gold layer on the spacer portion of the device surface. The gold layer may be hydrophobic. When the gold layer is not hydrophobic, a self-assembled monolayer (SAM) may be formed on the gold layer, and the SAM may be hydrophobic. In some implementations, treating the spacer portion may include selectively coating a hydrophobic adhesive on the spacer portion of the device surface.

Depending on the material of the device surface and the formation process used to fabricate the device surface, however, the device surface may not be substantially hydrophilic prior to treating the spacer portion of the device surface. In some implementations in which the device surface is not substantially hydrophilic, the device surface may be treated to render it hydrophilic. For example, the device surface may be coated with a hydrophilic material to render the device surface hydrophilic.

FIG. 12C shows an example of cross-sectional schematic illustration of the partially fabricated EMS assembly 1200 at this point (for example, up to block 1112) in the process 1004A of FIG. 11. The device surface 1214 of the second device layer 1208 includes spacer portions 1222 that have been treated to make attachment sites. In the depicted example, the spacer portions 1222 include the entire post areas 1218. In some other implementations (not depicted), the spacer portions 1222 may include only portions of the post areas 1218. For example, the spacer portions 1222 may not span the entire post areas 1218 shown in FIG. 12C.

At block 1114 in FIG. 11, the device surface is exposed to spacer particles suspended in a fluid. For example, to expose the device surface to spacer particles suspended in a fluid, the partially fabricated EMS assembly may be put into contact with or submerged in the fluid in which the spacer particles are suspended. In some implementations, the spacer particles may be suspended in water or deionized water. In some implementations, each of the spacer particles may have at least one dimension of about 1 micron to 10 microns. The spacer particles may include particles having any of a number of different shapes. In some implementations, the spacer particles may be spherical. In some other implementations, the spacer particles may have an irregular shape.

In some implementations, the spacer particles may be substantially hydrophobic. In some implementations, each of the spacer particles may have at least one substantially hydrophobic surface. For example, in some implementations, the spacer particles may include particles of silicon dioxide (SiO₂), gold (Au), or a polymer. Such spacer particles may be hydrophobic. In some other implementations, the spacer particles may not be substantially hydrophobic. When the spacer particles are not substantially hydrophobic, the spacer particles may be treated to render them substantially hydrophobic. Treatments for the spacer particles that are similar to the treatments described above to render a spacer portion of the device surface substantially hydrophobic may be used. For example, the spacer particles may be coated with a hydrophobic polymer.

At block 1116, spacer particles are allowed to attach to the spacer portion. In some implementations, spacer particles may attach directly to the spacer portion. In some other implementations, additional spacer particles may attach to spacer particles that have previously attached directly to the spacer portion. A period of time may be needed to allow the spacer particles to attach to the spacer portion. For example, in some implementations, about 5 minutes to 15 minutes or about 10 minutes may be an adequate time for which the spacer particles to attach to the spacer portion.

In some implementations, the driving force for the spacer particles attaching to the spacer portion is a free energy reduction of the system. For example, the system for the partially fabricated EMS assembly 1200 shown in FIG. 12C may be taken as the surfaces of the partially fabricated EMS assembly 1200 exposed to the fluid, the spacer particles suspended in the fluid, and the fluid (for example, water) itself. The free energy of this system may be reduced when hydrophobic surfaces are taken out of contact with water. Thus, a hydrophobic particle attaching to a hydrophobic spacer portion may reduce the area of hydrophobic surface in contact with water, reducing the free energy of the system.

At block 1118, the spacer particles are treated to bind them to the device surface. For example, in some implementations, the spacer particles may not be bonded to the device surface after the spacer particles are allowed to attach to the spacer portion. Thus, the spacer particles may be treated to bind them to the device surface. In some implementations, the treatment may include exposure to ultraviolet light or to heat to bind the spacer particles to the device surface.

FIG. 12D shows an example of cross-sectional schematic illustration of the partially fabricated EMS assembly 1200 at this point (for example, up to block 1118) in the process 1004A of FIG. 11. The device surface 1214 of the second device layer 1208 includes spacers 1232 formed on the spacer portions of the device surface. In some implementations, a spacer formed on a spacer portion of the device surface may be less than about 10 microns thick. For example, in some implementations, a spacer may be about 1 micron to about 6 microns thick.

Returning to FIG. 10, after forming the spacer at block 1004, a sacrificial layer may be removed from the EMS device at block 1022. In some implementations, the sacrificial layer may be removed by exposing the sacrificial layer to XeF₂. For example, when the sacrificial layer is Mo, W, or amorphous Si, the sacrificial layer may be removed by exposing the sacrificial layer to XeF₂. Other sacrificial layers and etchants may be used.

FIG. 12E shows an example of cross-sectional schematic illustration of the partially fabricated EMS assembly 1200 at this point (for example, up to block 1022) in the process 1000 of FIG. 10. Removing the sacrificial layer 1212 from the EMS device 1204 forms a cavity 1242 between the first device layer 1206 and the second device layer 1208 of the EMS device 1204. With the sacrificial layer 1212 removed, the second device layer 1208 may be supported by the posts 1210 and may be able to move into and out of contact with the first device layer 1206.

At block 1024, a cover is bonded to the substrate surface. In some implementations, the cover may be a transparent glass (for example, a borosilicate glass or a display glass) or a transparent plastic. In some other implementations, the cover may be an opaque plastic, glass, silicon, or metal. In some implementations, the cover may encapsulate the EMS device between the cover and the substrate. The cover may include a recess that defines a cavity when the cover is bonded to the substrate. The cover may be bonded to the substrate with an adhesive, such as epoxy, glass frit, or a metal bond ring.

In some implementations, the spacer is disposed between the cover and the device surface. In some implementations, the spacer is configured such that when a pressure is applied to the cover, the spacer may prevent contact between the cover and the device surface. For example, the spacer may prevent contact between the cover and the device surface when a force of about 5 N is applied to the cover.

FIG. 12F shows an example of cross-sectional schematic illustration of a fabricated EMS assembly 1201 at this point (for example, up to block 1024) in the process 1000 of FIG. 10. The fabricated EMS assembly 1201 includes the substrate 1202 and the EMS device 1204 on the substrate. The EMS device 1204 includes the first device layer 1206, the second device layer 1208, with the cavity 1242 between the first and second device layers. The posts 1210 support the second device layer 1208. The second device layer 1208 includes a device surface 1214, with spacers 1232 on the device surface 1214. The cover 1252 is bonded to the substrate surface and may encapsulate the EMS device 1204 between the cover 1252 and the substrate 1202. The spacers 1232 may prevent contact between the cover 1252 and the device surface 1214.

In some implementations, the spacers 1232 may include one or more spacer particles. In some implementations, the spacer particles may have at least one dimension greater than about 1 micron. In some implementations, the spacer particles may have at least one hydrophobic surface, as noted above.

In some implementations, the cover may include a desiccant (not shown) on a surface of the cover that is exposed to the EMS device when the cover is bonded to the substrate surface. The desiccant may remove moisture from the volume encapsulated between the cover and the substrate to improve the operation of the EMS device. When the cover includes a desiccant, the spacer also may prevent contact between the cover and/or the desiccant and the device surface.

While FIGS. 12A-12F depict the schematic illustrations of the partially fabricated EMS assembly 1200 and the fabricated EMS assembly 1201 as including one EMS device 1204, an EMS assembly may include an array of hundreds, thousands or even millions of EMS devices. A number of spacers may be formed on the device surfaces of the EMS devices. A cover may encapsulate the array of EMS devices. Further, the cross-sectional schematic illustrations of the partially fabricated EMS assembly 1200 shown in FIGS. 12A and 12C-12E and the fabricated EMS assembly 1201 shown in FIG. 12F depict the spacer portions of the device surface of EMS device as being substantially flat. Other EMS devices may include spacer portions of the device surface that are contoured or include other features, however.

As noted above, many different techniques may be used to fabricate spacers for an EMS device or an array of EMS devices. FIG. 13A shows an example of a flow diagram illustrating a manufacturing process for forming a spacer for an electromechanical systems assembly. The process 1004B shown in FIG. 13A may be used to form a spacer instead of using the process 1004A shown in FIG. 11; that is, process operations that may be included in block 1004 of FIG. 10 are shown in FIG. 13A.

Turning to FIG. 13A, at block 1301, the spacer portion of the device surface is treated to give the spacer portion a pattern or surface relief. For example, the spacer portion may be embossed or otherwise deformed. Embossing is a method of producing raised or sunken designs or relief in a structure. As another example, the spacer portion may have a material deposited on it with the material forming the desired pattern, or the desired pattern or surface relief may be etched into the material after deposition using lithography or other techniques.

The process 1004B continues at block 1114, as described above with respect to the process 1004A. At block 1114, the device surface is exposed to spacer particles suspended in a fluid. The spacer particles in the process 1004B may be contoured to fit the pattern of the spacer portion. Such spacer particles may be manufactured by forming a mold lithographically and forming the spacers from a polymer material using the mold, for example.

At block 1116, the spacer particles are allowed to attach to the spacer portion. In some implementations, a contoured surface of a spacer particle may fit a pattern formed on the spacer portion of the device surface. In some implementations, in addition to being patterned, the spacer portion can be an attachment site as described above. Furthermore, a contoured surface of a spacer particle can also be configured to attach to a pattern on the spacer portion of the device surface.

At block 1118, the spacer particles are treated to bind them to the device surface. The spacer particles may be treated to bind them to the device surface because the spacer particles may not be bonded to the device surface after the spacer particles are allowed to attach to the spacer portion. Details of some implementations of blocks 1114-1118 are described above with respect to FIG. 11.

FIGS. 13B and 13C show examples of cross-sectional schematic illustrations of a spacer portion and spacer particles according to the manufacturing process shown in FIG. 13A. Turning to FIG. 13B, the spacer portion 1302 includes a pattern 1304. A spacer particle 1306 includes a contoured surface that fits the pattern 1304 of the spacer portion. The patterns in the spacer portion can be a number of different patterns, and the patterns depicted in FIG. 13B are one example. A spacer particle 1306 may attach to the pattern.

Turning to FIG. 13C the spacer portion 1312 includes a pattern 1314. A spacer particle 1316 includes a contoured surface that fits the pattern 1314 of the spacer portion. The patterns in the spacer portion can be a number of different patterns, and the patterns depicted in FIG. 13C are one example. A spacer particle 1316 may attach to a pattern 1314.

While the process 1004A in FIG. 11 and the process 1004B in FIG. 13A are described as separate processes, in some implementations, some operations of these processes may be combined. For example, the spacer portion of a device surface, and in particular patterns 1304 and 1314, may be treated both to render the spacer portion substantially hydrophobic and to give the spacer portion a pattern. Similarly, the spacer particles may include a contoured surface and be hydrophobic. The spacer particles may attach to the spacer portion at block 1116 due to both the free energy reduction caused by a hydrophobic particle attaching to a hydrophobic spacer portion.

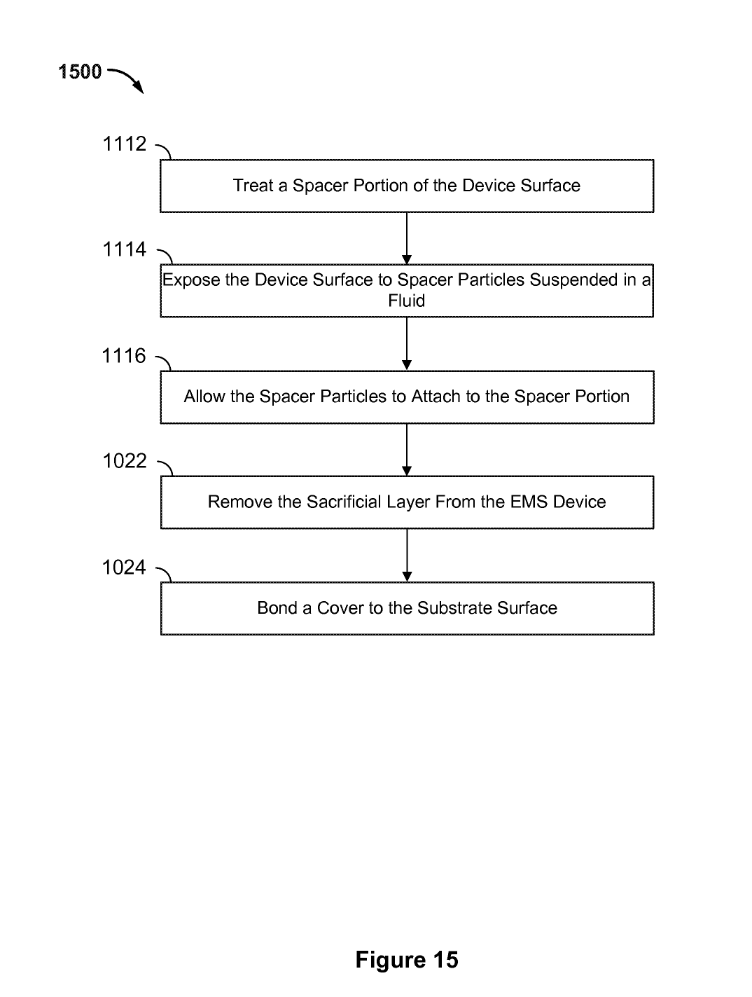

FIGS. 14 and 15 show examples of flow diagrams illustrating manufacturing processes for an electromechanical systems assembly including a spacer. The process 1400 shown in FIG. 14 includes some process operations described with respect to the process 1004A shown in FIG. 11. The process 1500 shown in FIG. 15 includes some process operations described with respect to the methods 1000 and 1004A shown in FIGS. 10 and 11, respectively.

Turning to FIG. 14, the process 1400 may be performed on a device surface of an EMS device. The EMS device may include a sacrificial layer between the device surface and a substrate surface of a substrate on which the EMS device is formed. The process 1400 starts with block 1114, as described above with respect to the process 1004A. At block 1114, the device surface is exposed to spacer particles suspended in a fluid. To expose the device surface to spacer particles suspended in a fluid, the partially fabricated EMS assembly may be put into contact with or submerged in the fluid having the particles suspended in it. At block 1116, the spacer particles are allowed to attach to the spacer portion. The spacer particles may attach to the spacer portion to reduce the free energy of the system. The spacer may prevent contact between the device surface and a cover that may be bonded to the substrate to encapsulate the EMS device between the cover and the substrate. Details of some implementations of blocks 1114 and 1116 are described above with respect to FIG. 11.

To complete the fabrication of the EMS assembly, the process 1400 may continue in some implementations with the process operations described above with respect to the processes 1000 and 1004A.

Turning to FIG. 15, the process 1500 may be performed on a device surface of an EMS device. The EMS device may include a sacrificial layer between layers of the EMS device or between a layer of the EMS device and a surface of the substrate on which the EMS is formed. The process 1500 starts with block 1112, as described above with respect to the process 1004A. At block 1112, a spacer portion of the device surface is treated to make an attachment site for spacer particles to later attach to. In some implementations, making an attachment site includes rendering the spacer portion of the device hydrophobic or electrically charged. Rendering the spacer portion substantially hydrophobic may aid in forming the spacer on the device surface. At block 1114, the device surface is exposed to spacer particles suspended in a fluid. The spacer particles may be substantially hydrophobic. To expose the device surface to spacer particles suspended in a fluid, the partially fabricated EMS assembly may be put into contact with or submerged in the fluid having the particles suspended in it. At block 1116, the spacer particles are allowed to attach to the spacer portion. In some implementations, each of the spacer particles has at least one dimension of about 1 micron to 10 microns. The spacer particles may attach to the spacer portion to reduce the free energy of the system.

After forming the spacer, at block 1022, the sacrificial layer is removed from the EMS device. The sacrificial layer may be removed by exposing the sacrificial layer to XeF₂ if the sacrificial layer is Mo, W, or amorphous Si. At block 1024, a cover is bonded to a substrate surface on which the EMS device is formed to encapsulate the EMS device between the cover and the substrate. The spacer may prevent contact between the device surface and the cover. Details of some implementations of blocks 1112 1114, 1116, 1022, and 1024 are described above with respect to FIGS. 10 and 11.

The processes disclosed herein may be used to form multiple spacers simultaneously. For example, at block 1004 of the process 1000 (FIG. 10), a plurality of spacers may be formed. This may include treating a plurality of spacer portions of the device surface to make a plurality of attachment sites by, for example, rendering the plurality of spacer portions of the device surface substantially hydrophobic, similar to block 1112 of the process 1004A (FIG. 11). Forming a plurality of spacers may also include exposing the device surface to spacer particles suspended in a fluid, with the spacer particles being substantially hydrophobic. In some implementations, a plurality of spacers may be formed on a device surface, with a greater density of spacers being formed at a center of an array of EMS devices than on the periphery of the array of EMS devices. In some other implementations, a plurality of spacers may be formed on a device surface, and each of the plurality of spacers may be positioned about 30 microns to 300 microns or about 30 microns to 50 microns from one another.

Many variations of the processes 1000, 1004A, 1004B, 1400, and 1500 may exist. For example, the EMS device may not include a sacrificial layer that is removed in the processes 1000 and 1500. As another example, a spacer portion of a device surface may not need to be treated in the processes 1004A, 1004B, or 1500. As yet another example, spacer particles may be treated to bind them to the device surface in the process 1500.

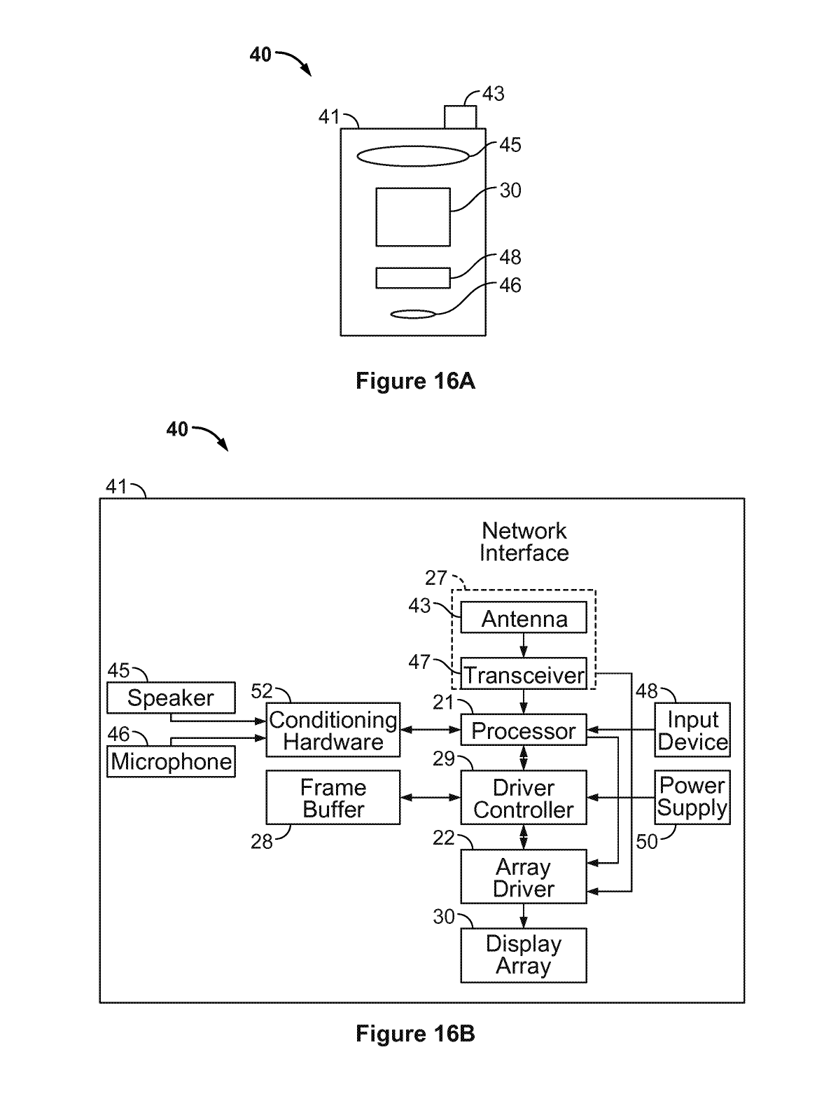

FIGS. 16A and 16B show examples of system block diagrams illustrating a display device 40 that includes a plurality of interferometric modulators. The interferometric modulators of the display device may include self-assembled spacers as described herein. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A method comprising:
forming a spacer on a spacer portion of a device surface of an electromechanical systems device, the device surface including an active area and a post area exclusive of the active area wherein the spacer portion is formed over the post area, the electromechanical systems device including a sacrificial layer between the device surface and a substrate surface of a substrate on which the electromechanical systems device is formed, wherein forming the spacer includes:
exposing the device surface to spacer particles suspended in a fluid, and
allowing the spacer particles to attach to the spacer portion, wherein each of the spacer particles has at least one dimension of about 1 micron to 10 microns.

2. The method as recited in claim 1, further comprising:
after forming the spacer, removing the sacrificial layer from the electromechanical systems device.

3. The method as recited in claim 2, wherein the sacrificial layer includes at least one of molybdenum, tungsten, or amorphous silicon, and wherein removing the sacrificial layer includes exposing the sacrificial layer to xenon difluoride.

4. The method as recited in claim 1, wherein forming the spacer further includes:
treating the spacer portion of the device surface to render the spacer portion substantially hydrophobic; and
after treating the spacer portion of the device surface, exposing the device surface to the spacer particles suspended in the fluid, wherein the spacer particles are substantially hydrophobic.

5. The method as recited in claim 1, wherein treating the spacer portion of the device surface includes:
selectively coating a hydrophobic adhesive on the spacer portion of the device surface.

6. The method as recited in claim 1, further comprising:
forming a plurality of the spacers to form an array of the spacers on the device surface, wherein each spacer in the array is positioned about 30 microns to 300 microns apart and wherein a center of the array has a greater density of spacers than a periphery of the array, and wherein forming the plurality of the spacers includes:
treating a plurality of spacer portions of the device surface to render the plurality of spacer portions of the device surface substantially hydrophobic; and
after treating the plurality of spacer portions of the device surface, exposing the device surface to the spacer particles suspended in the fluid, wherein the spacer particles are substantially hydrophobic.

7. The method as recited in claim 1, wherein forming the spacer further includes:
treating attached spacer particles to bind them to the device surface.

8. The method as recited in claim 7, wherein treating the attached spacer particles includes exposing the attached spacer particles to ultraviolet light or to heat.

9. The method as recited in claim 1, wherein the device surface includes at least one of aluminum, silicon oxynitride, or silicon nitride.

10. The method as recited in claim 1, wherein the spacer particles include particles of at least one of silicon dioxide, gold, or a polymer.

11. The method as recited in claim 1, wherein the spacer is less than about 10 microns thick.

12. The method as recited in claim 1, wherein a dimension of the spacer portion of the device surface is about 1 micron to 10 microns.

13. The method as recited in claim 1, further comprising:
bonding a cover to the substrate surface, wherein the cover encapsulates the electromechanical systems device between the cover and the substrate.

14. The method as recited in claim 13, wherein the spacer is disposed between the cover and the device surface.

15. The method as recited in claim 13, wherein the spacer is configured such that when a pressure is applied to the cover, the spacer prevents contact between the cover and the device surface.

16. A method comprising:
forming a plurality of spacers on a plurality of attachment sites on a device surface of an electromechanical systems device by exposing the device surface to spacer particles suspended in a fluid, the spacer particles including particles having at least one dimension of about 1 micron to 10 microns, wherein each of the plurality of spacers is positioned about 30 microns to 300 microns apart from one another on the device surface, and wherein forming the plurality of spacers includes:
treating the plurality of attachment sites on the device surface to render the plurality of attachment sites on the device surface substantially hydrophobic, and
after treating the plurality of attachment sites on the device surface, exposing the device surface to the spacer particles suspended in the fluid, wherein the spacer particles are substantially hydrophobic;
after forming the plurality of spacers, removing a sacrificial layer from the electromechanical systems device; and
bonding a cover to a substrate surface on which the electromechanical systems device is formed to encapsulate the electromechanical systems device between the cover and the substrate.

17. The method as recited in claim 16, wherein each of the plurality of spacers is less than about 10 microns thick.

18. The method as recited in claim 16, wherein the sacrificial layer includes at least one of molybdenum, tungsten, or amorphous silicon, and wherein removing the sacrificial layer includes exposing the sacrificial layer to xenon difluoride.

19. An apparatus comprising:
a substrate having a substrate surface;
an electromechanical systems device formed on the substrate surface, the electromechanical systems device having a first device layer and a second device layer, the first device layer and the second device layer defining a gap;
a cover bonded to the substrate surface, wherein the cover encapsulates the electromechanical systems device between the cover and the substrate; and
a self-assembled spacer on a device surface of the second device layer, wherein the spacer includes one or more spacer particles and is configured to prevent contact between the cover and the device surface, and wherein the spacer particles have at least one dimension greater than about 1 micron.

20. The apparatus as recited in claim 19, wherein the spacer is less than about 10 microns thick.

21. The apparatus as recited in claim 19, wherein each of the spacer particles have at least one hydrophobic surface.

22. The apparatus as recited in claim 19, wherein each of the spacer particles have at least one dimension of about 1 micron to 10 microns

23. The apparatus as recited in claim 19, wherein the spacer includes a spacer material of at least one of silicon dioxide, gold, or a polymer.

24. The apparatus as recited in claim 19, further comprising:
a display including a plurality of the electromechanical systems devices;
a processor that is configured to communicate with the display, the processor being configured to process image data; and
a memory device that is configured to communicate with the processor.

25. The apparatus as recited in claim 24, further comprising:
a driver circuit configured to send at least one signal to the display; and
a controller configured to send at least a portion of the image data to the driver circuit.

26. The apparatus as recited in claim 24, further comprising:
an image source module configured to send the image data to the processor.

27. The apparatus as recited in claim 26, wherein the image source module includes at least one of a receiver, transceiver, and transmitter.

28. The apparatus as recited in claim 24, further comprising:
an input device configured to receive input data and to communicate the input data to the processor.
